(19) United States
(12) Patent Application Publication
(10) Pub. No.: US 2025/0233384 A1
(43) Pub. Date: Jul. 17, 2025

(54) CONVERSION ELEMENT WITH POROUS LAYER

(71) Applicant: Lumileds LLC., San Jose, CA (US)

(72) Inventors: Hans-Helmut BECHTEL, Roetgen (DE); Ronald MIKKENIE, Simpelveld (NL); Oliver STEIGELMANN, Aachen (DE); Antonio LOPEZ-JULIA, Vaals (NL); Niels Jeroen VAN DER VEEN, Schiphol (NL)

(73) Assignee: Lumileds LLC., San Jose, CA (US)

(21) Appl. No.: 19/095,757

(22) Filed: Mar. 31, 2025

Related U.S. Application Data
(63) Continuation of application No. PCT/US2023/035601, filed on Oct. 20, 2023.
(60) Provisional application No. 63/427,509, filed on Nov. 23, 2022.
(60) Provisional application No. 63/418,367, filed on Oct. 21, 2022.

(51) Int. Cl. H01S 5/00; H01S 5/06; H01S 5/125; H10H 20/851

(52) U.S. Cl. CPC H01S 5/0087; H01S 5/0611; H01S 5/125; H10H 20/8513

(57) ABSTRACT

This specification discloses a converter element and light emitting devices including the converter element. The converter element is monolithic with at least two layers, where one layer is more porous than the other layer. The converter element may be integrated with a reflector layer, such as by metallization. The layer of the converter structure that is denser and having a smoother surface may be the one that is metallized, while the more porous layer is closer to the laser. The porosity enhances light extraction while the smoother surface decreases a loss of reflectivity at the reflector-phosphor interface. The converter element may be used in a laser based light emitting device.

### CROSS REFERENCE TO RELATED APPLICATIONS

This application is a continuation of PCT Application PCT/US2023/035601, titled “WAVELENGTH CONVERTING STRUCTURE AND METHOD OF MANUFACTURING THE SAME” filed Oct. 20, 2023, which claims priority to U.S. Provisional Patent Application 63/418,367 titled “CONVERSION ELEMENT WITH POROUS LAYER” filed Oct. 21, 2022, and to U.S. Provisional Patent Application 63/427,509 titled “CONVERSION ELEMENT WITH POROUS LAYER” filed Nov. 23, 2022. All of the above-mentioned applications are incorporated herein by reference in their entirety.

### FIELD OF THE INVENTION

The invention relates generally to light emitting structures, particularly those with at least one protective layer preventing degradation of one or more components, and methods for fabricating such structures.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Such LEDs and pcLEDs may be arranged in arrays for use, for example, in automotive vehicles, and for general illumination including indoor and outdoors. Specifically, lasers can be used in any application where a small intense light source that can be imaged is needed. The laser may be visible light or it may be infrared light. The laser may be incident on the phosphor module from a same side as the laser light and the converted light is to be emitted from the phosphor module. For example, the laser light may mix with the converted light to produce white light. Consequently, the phosphor module needs to be reflective to at least the laser light and converted light. The reflective layer attached to the phosphor in the module needs to adhere well in the device, and commonly a glue interface is used to achieve that adherence. However, using a glue interface between the phosphor and the reflective layer may cause thermal issues and reflectivity issues, decreasing the light efficiency of the device.

### SUMMARY

This specification discloses a phosphor converter structure with two layers of differing porosity. The converter structure may be monolithic. The converter structure may be further integrated with a reflector layer, such as by metallization. The layer of the converter structure that is denser and having a smoother surface may be the one that is metallized, while the more porous layer is closer to the laser. The porosity enhances light extraction while the smoother surface decreases a loss of reflectivity at the reflector-phosphor interface.

The LED arrays disclosed herein may be advantageously employed in, for example, any of the devices and applications listed above in the Background section or below.

Other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross sectional view of an array of pcLEDs arranged with respect to waveguides and a projection lens. FIG. 4B shows an arrangement similar to that of FIG. 4A, without the waveguides.

FIG. 5 schematically illustrates an example camera flash system comprising an adaptive illumination system.

FIG. 6 shows a cross sectional view of number of tapes being brought together for lamination, some of the tapes including pore-formers and one of the tapes without pore-formers.

FIG. 7 shows a converter structure with two layers, one layer having pores and one layer without less or no pores.

FIG. 8 illustrates a reflective converter module including the converter structure of FIG. 7 along with other layers such as reflective layers.

FIG. 9 illustrates a converter structure with three layers, one layer having pores and two layers without.

FIG. 10 illustrates a converter structure with three layers, two layer having pores and one layer without.

FIG. 11 depicts a luminance profile for a laser beam on different converter structures.

FIG. 12 depicts SEM images of two layers of Lumiramic.

FIG. 13 illustrates a light emitting laser device including a converter module attached to a heat sink.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

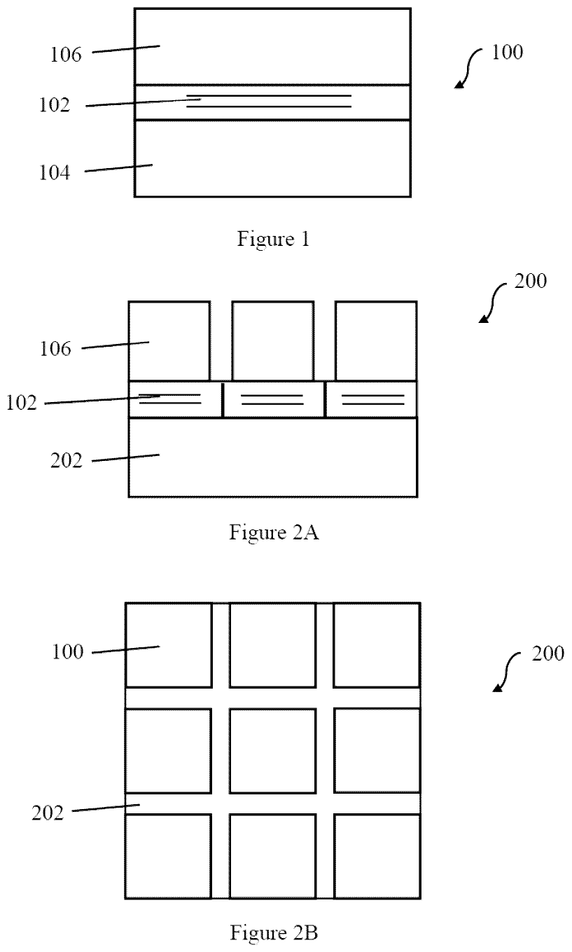

FIG. 1 shows an example of an individual pcLED 100 comprising a light emitting semiconductor diode structure 102 disposed on a substrate 104, and a phosphor layer 106 disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output from the pcLED.

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED, and may be formed from any suitable materials.

Although FIGS. 2A-2B, show a three-by-three array of nine pcLEDs, such arrays may include for example tens, hundreds, or any suitable number of LEDs. Individual LEDs (pixels) may have widths (e.g., side lengths) in the plane of the array of, for example, less than or equal to 1 millimeter (mm), less than or equal to 500 microns, or less than or equal to 100 microns. LEDs in such an array may be spaced apart from each other by streets or lanes having a width in the plane of the array of, for example, greater than a millimeter, less than or equal to a millimeter, or less than or equal to 500 microns. Although the illustrated examples show rectangular pixels arranged in a symmetric matrix, the pixels and the array may have any suitable shape.

The individual LEDs in an LED array may be individually addressable, may be addressable as part of a group or subset of the pixels in the array, or may not be addressable. Thus, light emitting diode arrays are useful for any application requiring or benefiting from fine-grained intensity, spatial, and temporal control of light distribution. These applications may include, but are not limited to, precise special patterning of emitted light from pixel blocks or individual pixels. Depending on the application, emitted light may be spectrally distinct, adaptive over time, and/or environmentally responsive. Such light emitting pixel arrays may provide pre-programmed light distribution in various intensity, spatial, or temporal patterns. The emitted light may be based at least in part on received sensor data and may be used for optical wireless communications. Associated electronics and optics may be distinct at a pixel, pixel block, or device level.

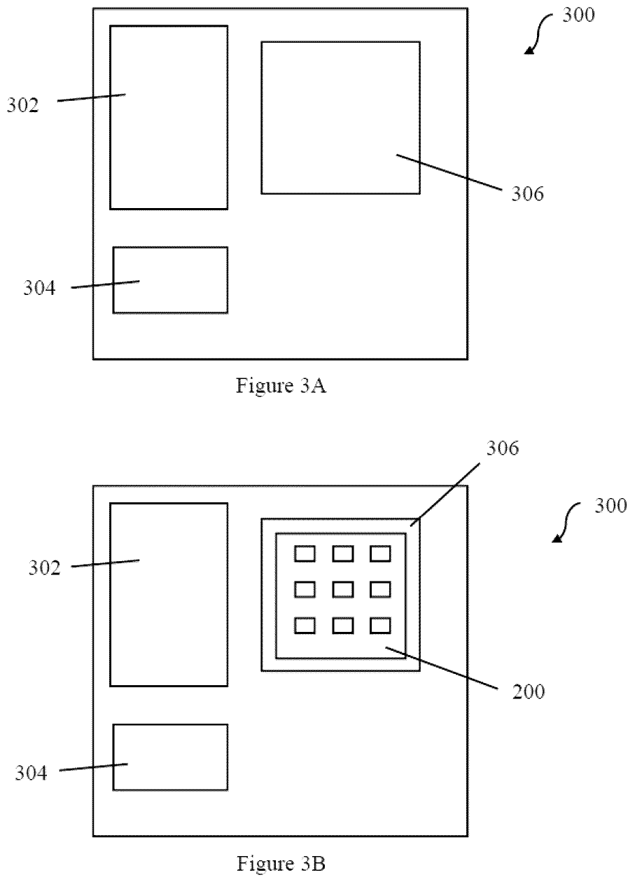

As shown in FIGS. 3A-3B, an LED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, LED array 200 may be mounted on a separate board (not shown) from the power and control module and the sensor module.

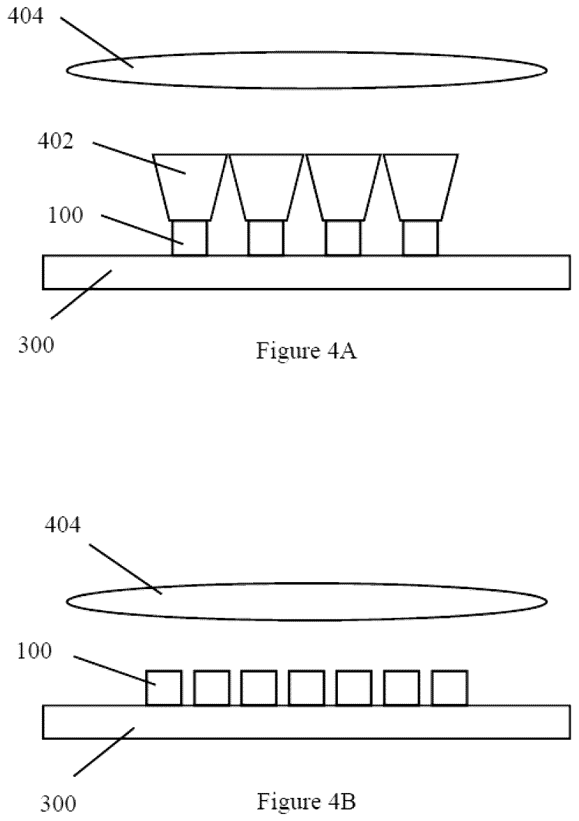

Individual LEDs and pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an LED array 200 (for example, mounted on an electronics board 300) may be arranged in combination with secondary optical elements such as waveguides, lenses, or both for use in an intended application, for example as precollimators. In FIG. 4A, light emitted by pcLEDs 100 is collected by waveguides 402 and directed to projection lens 404. Projection lens 404 may be a Fresnel lens, for example. This arrangement may be suitable for use, for example, in interior automobile illumination, automobile headlights, and other exterior automobile illumination. In FIG. 4B, light emitted by pcLEDs 100 is collected directly by projection lens 404 without use of intervening waveguides. This arrangement may particularly be suitable when the LEDs or pcLEDs can be spaced sufficiently close to each other. Generally, any suitable arrangement of optical elements may be used in combination with the LED arrays described herein, depending on the desired application.

An array of independently operable LEDs may be used in combination with a lens, lens system, or other optical system (e.g., as described above) to provide illumination that is adaptable for a particular purpose. For example, in operation such an adaptive lighting system may provide illumination that varies by color and/or intensity across an illuminated scene or object and/or is aimed in a desired direction. A controller can be configured to receive data indicating locations and color characteristics of objects or persons in a scene and based on that information control LEDs in an LED array to provide illumination adapted to the scene. Such data can be provided for example by an image sensor, or optical (e.g. laser scanning) or non-optical (e.g. millimeter radar) sensors. Such adaptive illumination is increasingly important for automotive and illumination applications.

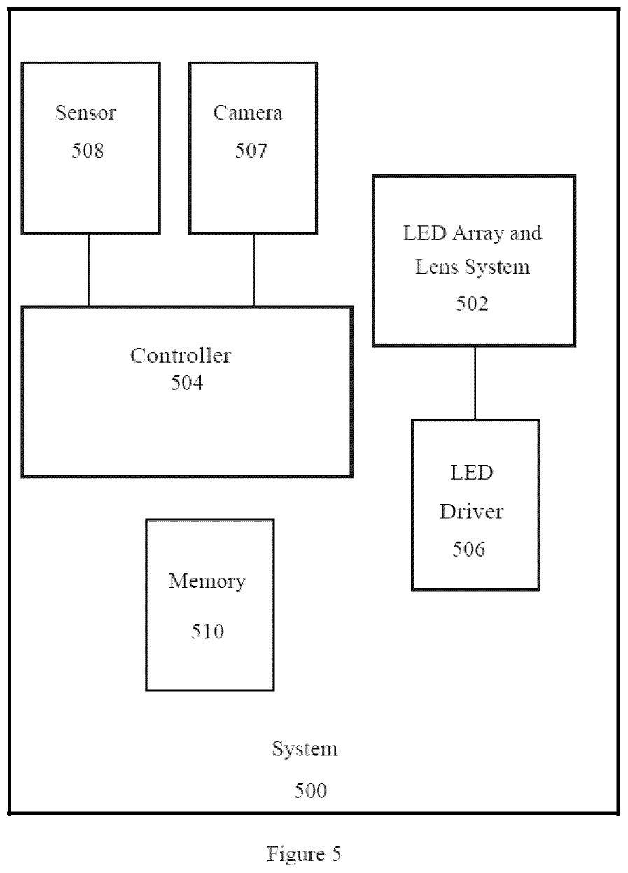

FIG. 5 schematically illustrates an example camera flash system 500 comprising an LED array and lens system 502, which may be similar or identical to the systems described above. Flash system 500 also comprises an LED driver 506 that is controlled by a controller 504, such as a microprocessor. Controller 504 may also be coupled to a camera 507 and to sensors 508, and operate in accordance with instructions and profiles stored in memory 510. Camera 507 and adaptive illumination system 502 may be controlled by controller 504 to match their fields of view.

Sensors 508 may include, for example, positional sensors (e.g., a gyroscope and/or accelerometer) and/or other sensors that may be used to determine the position, speed, and orientation of system 500. The signals from the sensors 508 may be supplied to the controller 504 to be used to determine the appropriate course of action of the controller 504 (e.g., which LEDs are currently illuminating a target and which LEDs will be illuminating the target a predetermined amount of time later).

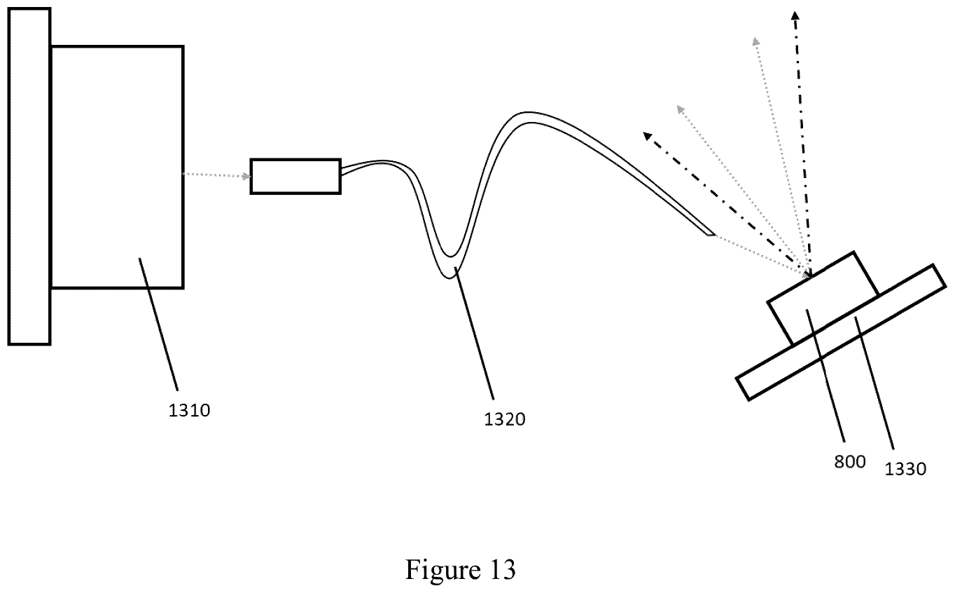

In operation, illumination from some or all pixels of the LED array in 502 may be adjusted—deactivated, operated at full intensity, or operated at an intermediate intensity. Beam focus or steering of light emitted by the LED array in 502 can be performed electronically by activating one or more subsets of the pixels, to permit dynamic adjustment of the beam shape without moving optics or changing the focus of the lens in the lighting apparatus. Embodiments of the invention may include a laser source incident on phosphor. FIG. 13 depicts such a laser light source. Laser based light sources are used to generate very high luminance (>1GCd/m²) within spot sizes well below 0.5 mm² in diameter. The laser 1310 may be a blue laser focused onto a converter module 800. The converter module may be located on a heat sink 1330. Both reflected laser light and emitted light from the phosphor layer are leaving the converter module in an emission direction. The laser beam may travel through an optical fiber 1320 as shown. Alternatively, the laser light source and converter module can also be integrated directly in one module (without a fiber in between).

In order to realize a high efficiency of the device, the converter module has to fulfil numerous optical, mechanical and thermal properties. Optical properties have been realized with, for example, a highly scattering, thin Lumiramic (ceramic phosphor platelet) converter, glued to a metallic reflector with a very thin silicone layer. However, this silicone layer forms a thermal resistor, limiting heat transport to the metal and heat sink, limiting the maximum power dissipation. In phosphor conversion processes more than 20 percent of the incoming light is converted directly to heat, due to Stokes losses in the down-conversion process.

In order to increase the thermal conductivity of the converter module, a metal reflector may be evaporated on the Lumiramic directly, instead of glued. After deposition of additional metal layers on the reflector layer, the converter module is directly soldered to the heat sink. However, deposition of a metal reflector layer on the highly scattering phosphor shows low reflectance at the Lumiramic/metal interface. This is because the highly scattering phosphor is often implemented as a porous phosphor to obtain that high scattering. The metallization of the rough, porous phosphor surface leads to metal being deposited into the pores at the interface between the phosphor and the metal. As a result there is low reflectance at the interface. In order to solve this problem, embodiments of this invention combine high scattering power in a porous phosphor body, with a less porous body having a smoother surface, which leads to high reflectance at the converter-reflector interface.

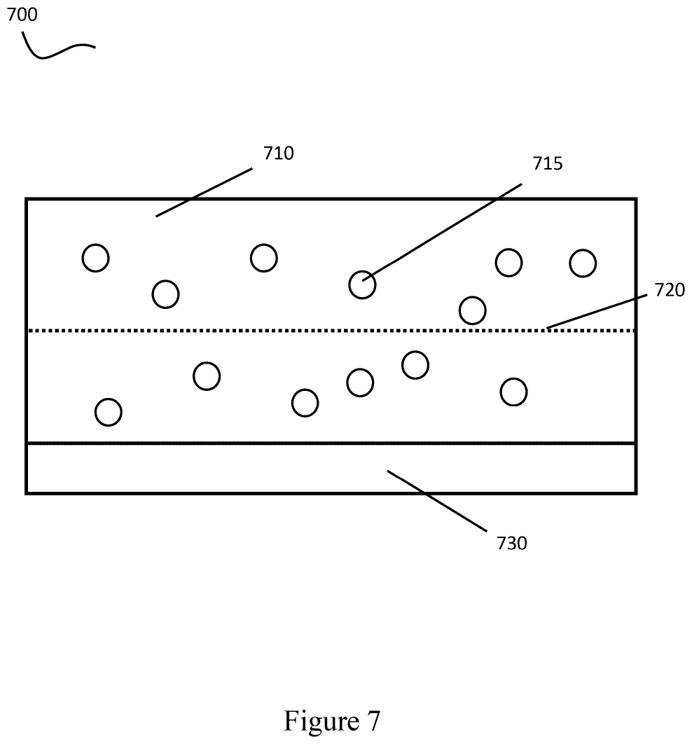

FIG. 7 depict a converter structure 700 with a first layer 710 disposed on a second layer 730. The converter structure 700 is made of a wavelength converting material that absorbs light of a first wavelength and emits light of a second wavelength, such as a ceramic phosphor, e.g., an yttrium aluminum garnet (YAG) phosphor, or a BSSN phosphor. The first wavelength may be of a blue light, and the second wavelength may be that of a different visible color, such as yellow, green, red, or orange. Alternatively, one of the first or second wavelength can be infrared or near-infrared. That is, either of the first and second wavelength may have wavelengths from 400-2000 nm, such as from 400-700 nm or 800-2000 nm. For example, the first wavelength may be blue light with the phosphor emitting infrared light. Both the first layer 710 and the second layer 730 may be made of the same material, that is, be or include the same elements and/or the same compounds. The first and second layer may have the same absorption wavelength and emission wavelength. However, they differ in that the first layer 710 has a high porosity compared to the second layer 730. First layer 710 comprises pores 715. The pores 715 may be filled with air or may comprise vacuum. Alternatively, the pores 715 may be filled with Al₂O₃ as second phase particles functioning as scattering centra. Second layer 730 may comprise no pores, substantially no pores, or relatively less pores compared to first layer 710. Converted photons in the phosphor may get totally internally reflected at the light emission surface at the phosphor/air interface, leading to a waveguide effect transporting the converted light to the edges of the phosphor rather than the top emitting side. Scattering in the body of the material prevents this waveguide effect, and desirably distributes pump light and converted light at all angles.

The first layer may, for example, have a density <99%, while the second layer has a density >99%, since the first layer's density is reduced by the pores. The first layer may have a porosity of about 5-10 percent, for example about 5-7 percent, for example at or about 7 percent. The second layer may have a porosity of about 0-2 percent, for example about 0-0.5 percent, for example at or about 0.5 percent.

The first layer 710 is disposed directly on the second layer 730 to be in direct contact. They may be sintered together to form a monolithic, solid ceramic body. The first layer 710 may be thicker than the second layer 730 (in a shortest dimension of the layer, e.g., a direction perpendicular to a plane of contact between the layers). For example, if Ti is the thickness of the first layer and T₂ is the thickness of the second layer, the ratio of the thickness may be T₁:T₂>1, for example, T₁:T₂>3, for example, T₁:T₂>4. The first layer may have a same width as the second layer, the width being perpendicular to the thickness. However, this is not a requirement, and the first layer may have a different width than the second layer, such as a smaller width. The volume and density of the pores in the first layer may be adjusted as long as the first layer has greater porosity compared to the second layer. The porosity may be closed porosity. The diameter of each pore Dₚₒᵣₑ may be 0.5 μm≤Dₚₒᵣₑ≤20 μm, e.g., 1 μm≤Dₚₒᵣₑ≤5 μm. The pores may be spherical or substantially spherical in shape. As a result of the pores, the first layer may be highly scattering to one or both of the light of the first and second wavelength. On the other hand, second layer having less or no pores has a much smoother bottom or top surface compared to the first layer. This makes the second layer much more suitable for interfacing/attaching with a reflector layer, as will be described below.

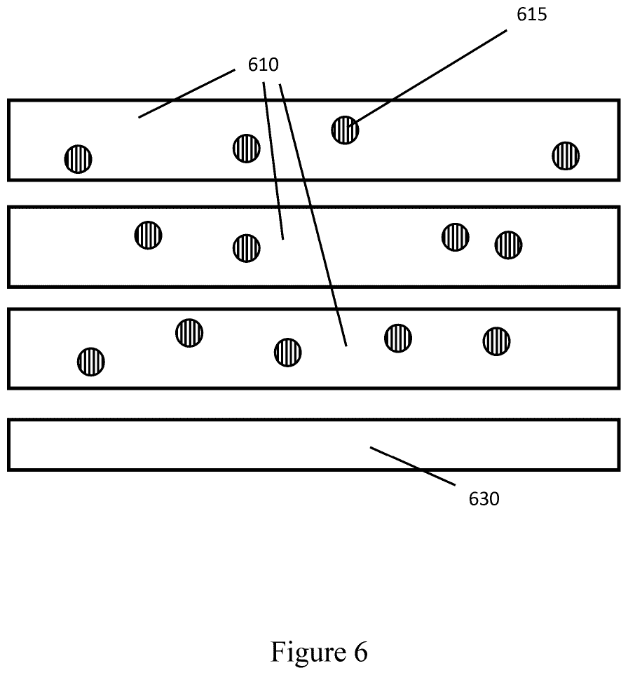

FIG. 6 shows a process for forming the converter structure 700. Multiple tapes 610 and 630 may be formed separately from each other, and then laminated together. Tapes 610 are casted and dried after a suspension of, e.g., metal oxides, dispersants, binders, plasticisers, and the so-called pore-formers 615 was made. For example, the dispersants may be Malialim AKM-0531 (NOF America), Hypermer KD-1 or Disperbyk-108; the binders may be Polyvinylbutyral (PVB) B76 or other types of PVB; the plasticizer may be Plasticizer G260 (Sekisui Chemical) or alternatively Benzyl butyl Phtalate (BBP) (these plasticizer materials can be used in combination with polyethyleneglycol (PEG), which can have various molecular weights (Mw)). The pore-formers 615 may be particles, for example substantially spherical organic particles. The suspension will be tapecasted (foilcasted) to yield dried tapes 610. The tape is then cut into sheets of desired dimensions. A second tape 630 is made by casting a similar type of suspension, but without the use of pore-formers 615. All sheets will be made according specified dimensions. Both tapes 610 and second 630 can be made at different thicknesses and do not need to have same thickness. Alternatively, both types of tapes 610 and 630 can each be of the same thickness. The tapes 610 and second tape 630 put on top of each other to end up with a pile of tapes/sheets, and when pressed, the process is called lamination. Tapes 610 will be laminated in such way that the pile thickness is add up to the thickness of first layer 710 in FIG. 7. Tapes 610 are laminated to each other and to tape 630. The tape 630 may be formed initially as a single sheet. Alternatively, in embodiments of this invention, there are multiple tapes 630 laminated together to form a thickness of second layer 730 as depicted in FIG. 7 (which is also laminated to the tapes 610). After the lamination process, the stack goes into a binder burn out process, to remove the pore-formers 615. As the pore-formers are burned out, they leave behind pores like those shown in FIG. 7. Thereafter, the materials may be fired at high temperatures to undergo reactive sintering, whereby the desired garnet ceramics are formed via a diffusion reaction and simultaneously densifying of the particles to form a highly dense ceramic.

Alternatively or additionally, the first layer 710 may be itself formed of two or more phosphor layers that has an interface 720 between them as shown in FIG. 7. The phosphor layers in the first layer 710 may be or comprise different materials from each other, and/or emit light of different wavelengths from each other. For example, one of the phosphor layers may emit green light and the other may emit red light. For example, one of the phosphor layers may be a YAG phosphor, while the other is a BSSN phosphor. Both of the phosphor layers may be ceramic phosphors, although this is not a requirement. Both of the phosphor layers may have pores 715 within them in order to improve scattering, and may have the same porosity as each other, although this is not a requirement and they may have different porosities as each other. The phosphor layers may be in direct contact with each other at the interface 720, or there may be an adhesion layer in between them to bond them to each other. When the first layer 710 includes multiple phosphor layers, the second layer 730 may be made from the same materials as one of the layers, and be or comprise different materials from at least one of the other layers. For example, the second layer 730 may be in direct contact with one of the phosphor layers in first layer 710 that has a same phosphor material as itself, or it may be in direct contact with one of the phosphor layers in first layer 710 that has different phosphor materials as itself, which spaces apart second layer 730 from the phosphor layer in first layer 710 that has a same material as itself. One or more of the multiple phosphor layers within the first layer 710 and/or the second layer 710 may absorb light emitted by one of the other layers to emit light.

Alternatively, the first layer 710 may be or comprise a phosphor layer of a single phosphor material while the second layer 730 is or comprise a phosphor layer of a single phosphor material different from that of the first layer 710. For example, the first layer 710 may comprise a YAG phosphor while the second layer 730 comprises a BSSN phosphor. The first layer 710 and second layer 730 may in this case emit light of different wavelengths from each other, such as green and red, respectively. Both the first layer 710 and second layer 730 may be ceramic phosphors, although this is not a requirement, the second layer 730 may for example be of a non-ceramic phosphor.

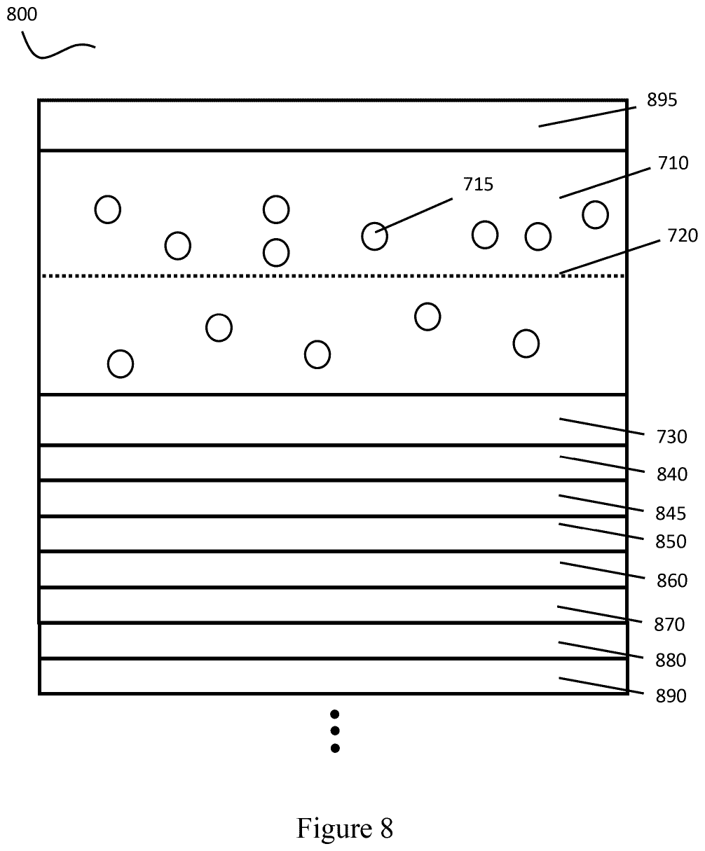

The resulting converter structure 700 may form part of a stack with other layers to result in a converter module 800 in a light emitting device. The converter structure 700 may be metalized via vacuum deposition processes, whereby a layer of low refractive index is deposited on the second layer 730. For example, a layer of SiO₂ may be deposited on the second layer 730, having a lower refractive index than the second layer 730. A mirror is applied via for example a sputtering process. On top of the mirror various option of metal layers can be deposited, depending on the properties needed. FIG. 8 shows the reflective converter module 800, with the first layer 710 and second layer 730 stacked with other layers. For example, intermediate layer 840 may be SiO₂ and/or an interferometric layer, layer 845 may be or include an adhesion promoter (e.g., aluminum oxide) and/or a Distributed Bragg Reflector (DBR), main metal layer 850 may be Ag, Au or Al, and first through fourth metal cover layers 860, 870, 880, and 890 may each be any of Ni, Cr, and Au. For example, an interferometric layer may be a low refractive index layer of SiO₂ of about 500 nm, covered with an 80 nm ZrO₂ high refractive index; more high refractive layers can optionally be added on top of the ZrO₂ at quarter lambda thickness. For example, first metal cover layer 860 may be Ni, second metal cover layer 870 may be Cr, third metal cover layer 880 may be Ni, and fourth metal cover layer 890 may be Au. Intermediate layer 840 may be at a thickness of about 600-700 nm, for example, at or about 500 nm. The intermediate layer 840 may be at a lower refractive index than the second layer 730. This lower refractive index helps the reflectivity of the overall device since there it smooths the refractive index difference between the converter structure 700 and the main metal layer. The main metal layer may be at or about 50-200 nm, for example at or about 100-150 nm, for example at or about 100 nm.

Layer 845 may be between intermediate layer 840 and main metal layer 850. Layer 845 may be or include an adhesion promoter and/or may be or include DBR. When layer 845 includes an adhesion promoter, the adhesion promoter may be at 5-10 nm of thickness, and increase adhesion between the intermediate layer and the main metal layer. The adhesion promoter may be aluminum oxide, which may be less absorbing of certain wavelengths of light like chromium might be. Additionally or alternatively, layer 845 may be or include a DBR of thickness 100 nm to 1 microns. The DBR serves as an interferometric layer. The DBR may comprise multiple layers of varying refractive indices. When the layer 845 includes the DBR, it may or may not be include the adhesion promoter. That is, layer 845 may include the adhesion promoter by itself, the DBR by itself, or both in combination. When the adhesion promoter is included, it may be in direct contact with the main metal layer. In an example, intermediate layer 840 is SiO₂, layer 845 is DBR without including the adhesion promoter, main metal layer 850 is Ag, Au, or Al, and the DBR of layer 845 is in direct contact with both intermediate layer 840 and main metal layer 850.

There may be more or less layers than is depicted in FIG. 8. For example, in embodiments of the invention, one or more of the intermediate layer 840 and the adhesion promoter 845 may be omitted and main metal layer 850 may be disposed in direct contact with the second layer 730. Such a structure may be easier to manufacture, and the adhesion of the main metal layer 850 to the converter structure 700 may be better without the intermediate layer 840 in between. Other layers may be omitted, such as layers 860, 870, 880, 890, depending on the characteristics of reflectivity required in the stack. In embodiments of the invention, additional layers may be disposed on layer 890, such as metal layers of different and/or alternating types of metals. The composition of layers 840-890 may depend upon the type of light emitting device desired. For example, main metal layer 850 may be Ag for garnet phosphors and Au for infrared converters.

Additionally, a dichroic filter 895 may be disposed on the first layer 710. The dichroic filter 895 may serve as an anti-reflection structure for the first wavelength, that is, the wavelength of the absorption or laser light incident on the phosphor to excite it. The dichroic filter 895 increases transmission of light into the phosphor. Particularly, the dichroic filter 895 may increase the transmission of light, e.g. blue laser, into the phosphor at the angle of incident of the light (which is often at a non-perpendicular angle). The dichroic filter may comprise multiple alternating layers of high and low refractive index layers that together causes the anti-reflectivity and increased transmission of the pump light, such as 12-13 layers, or just one quarter lambda layer with refractive index in the range of 1.3-1.5. The dichroic filter may be deposited onto the converter structure 700 after the converter structure 700 is fully formed (e.g., after reactive sintering). The dichroic filter may be deposited directly on the first layer 710 to be in direct contact with it. The dichroic filter may be deposited before the layers 840-890 are deposited; alternatively, the dichroic filter may be deposited after the layers 840-890.

Additionally, the dichroic filter 895 may also be reflective for infrared light. In embodiments of the invention, laser 1310 may be or include an infrared light. Even though the metal layers, which may include Ag or Au, may already be reflective for infrared light, the additional reflectivity of the dichroic filter 895 disposed on the scattering side of the converter structure 700 rather than the smoother side of the converter structure 700 (which the metal layers are disposed on) may lead to better homogeneity and distribution of infrared light incident on the converter module 800. That is, it may be better to reflect the infrared light at the top of the converter module 800 rather than at the interface between the converter structure 700 and the metal layers. The infrared light may be used in, for example, camera detection of obstacles, such as in automotive applications. Materials for dichroic filter layers are the same as in the visible range, using HL refractive index pairs of quarter lambda layer. Pairs can be: SiO2/TiO2, SiO2/Nb2O5, etc.

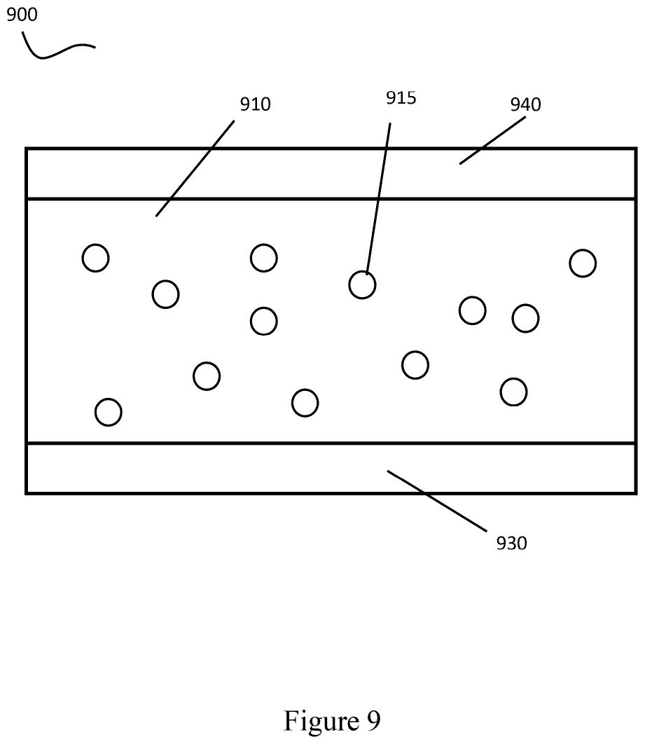

FIG. 9 depicts a converter structure 900 with a first layer 910 between a second layer 930 and a third layer 940. The first layer 910 and second layer 930 are similar or identical with the corresponding elements described above in FIGS. 6-8. The third layer 940 may be similar or identical with the second layer 930 in characteristics such as porosity and material composition. However, it is disposed on the opposite side of the converter structure 900 compared to the second layer 930. That is, the third layer 940 may be disposed directly on the first layer 910 on an opposite surface to the second layer 930. The first layer 910 is then sandwiched between the lower porosity layers of the second and third layer 930 and 940. Such a converter structure 900 may be more mechanically strong compared to a converter structure with a lower porosity layer disposed only on one side of the first layer 910. As with the converter structure(s) described above, converter structure 900 may be integrated with a structure similar or the same as that depicted in FIG. 8.

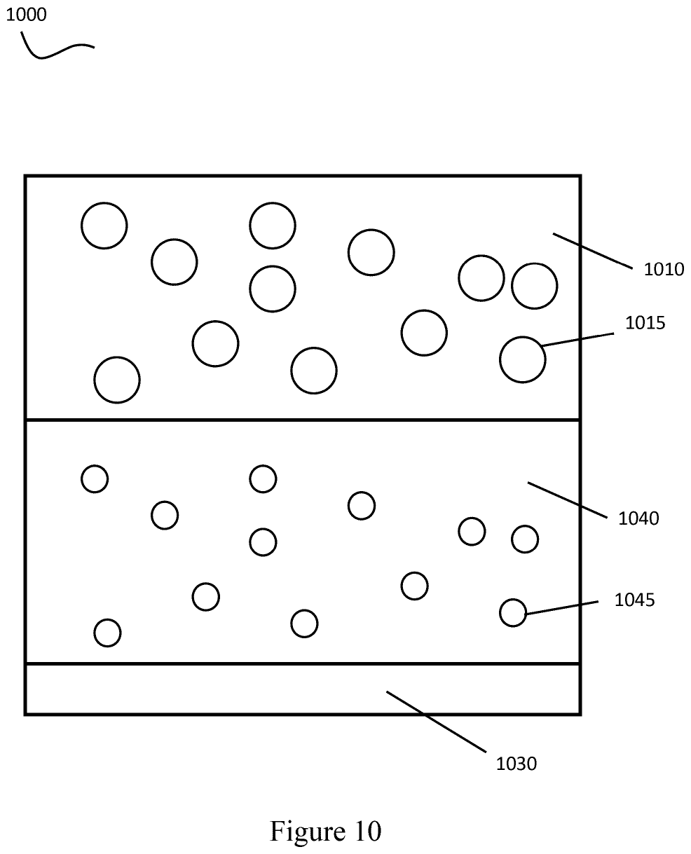

FIG. 10 depicts a converter structure 1000 with first layer 1010, second layer 1030, and third layer 1040 between the first and second layers. The first layer 1010 and second layer 1030 may have similar or identical characteristics with the first and second layers described above in FIGS. 7-9. The third layer 1040 may be similar or identical with the first layer 910 in characteristics such as porosity and material composition. The third layer 1040 has pores 1045 formed in the same as pores 1015, e.g., with pore-formers that are eventually burned out. However, the pores 1045 may have at least one of a different density, size, shape, number, and/or other physical or quantitative characteristics as pores 1015; in cases where individual pores 1045 are different from pores 1015 the pore-formers used to form them are correspondingly different. As a result, the third layer 1040 may have a higher or lower porosity compared to the first layer 1010, i.e., higher or lower density. In embodiments of the invention, the pores 1045 having at least one different characteristic than the pores 1015 may still result in the first and third layers having a same porosity/density. The third layer 1040 may have a higher porosity than the second layer 1030, which has no pores or substantially no pores. The third layer 1040 may have a same thickness as the first layer, or a different thickness. The third layer 1040 may have a greater thickness than the second layer 1030. As with the converter structure(s) described above, converter structure 1000 may be integrated with a structure similar or the same as that depicted in FIG. 8.

Embodiments of the invention may include more layers including pores than just the first layer 1010 and third layer 1040 (e.g., 3-10 layers, e.g., 3-5 layers). The layers with pores may have increasing or decreasing porosity progressing from the top surface to the bottom surface approaching the second layer 1030, or they may have alternating porosity from each other.

The reflectance of the reflective converter module 800 may be characterized by measuring Quantum Efficiency (QE), i.e. the number of emitted photons from the converter element divided by the number of blue photons absorbed by the converter element. Table 1 shows the experimentally measured QE of Comparative Examples with single layer converter structures being lower than dual layer converter structures including the thin low porosity second layer, which are embodiments of the invention. Both the Comparative Examples and embodiments of the invention are stacked with a layer of Ag of 100 nm thickness or an SiO₂ intermediate layer of 500 nm with the Ag layer.

TABLE 1
Quantum efficiency of converter elements (wafers).
All with 100 nm Ag coating

| Converter Element | QE | |
|---|---|---|
| High porosity Mono-LR-Ag (100 nm) | 69% | Comparative Example |
| High porosity Mono-LR-SiO₂(500 nm)- | 72% | Comparative Example |
| Ag (100 nm) | | |
| Dual LR (with thin low por. Layer)- | 76% | Embodiment of the |
| Ag (100 nm) | | Invention |
| Dual LR (with thin low por. | 81% | Embodiment of the |
| Layer)-SiO₂(500 nm)-Ag (100 nm) | | Invention |

As demonstrated, it is essential to have a highly scattering phosphor layer in the conversion element, to realize a high luminance. This performance is not adversely changed with the addition of the thin low porosity layer.

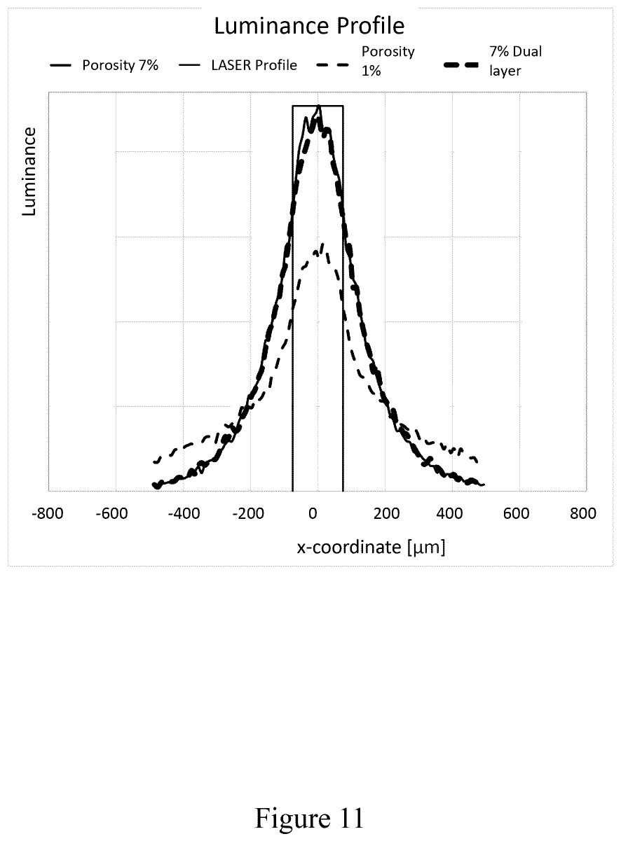

FIG. 11 shows the experimentally measured luminance profile for the examples and embodiments in Table 1. The luminance distribution is for a laser beam of 130 μm diameter falling on different conversion elements. The single line shows High porosity Mono layer LR with SiO₂ (500 nm) and 100 nm Ag reflector. The dashed line shows Low porosity Mono layer LR with SiO₂ (500 nm) and 100 nm Ag reflector. The thick dashed line shows High/low porosity Dual (5 μm) layer LR with SiO₂ (500 nm) and 100 nm Ag reflector (normalized to single line Mono layer).

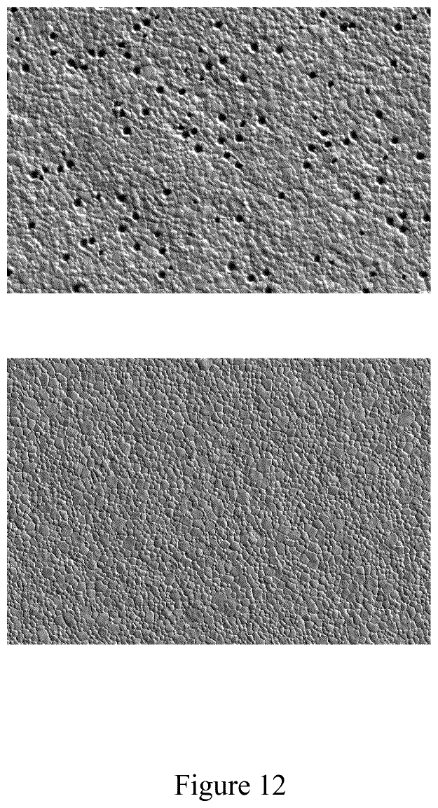

FIG. 12 shows SEM images of Lumiramic surfaces. The top image shows Lumiramic surface (with the garnet micro crystals and high density of holes is present on the surface) corresponding to the pore filled first layer 710. The bottom image shows the smooth surface corresponding to the second layer 730.

This disclosure is illustrative and not limiting. Further modifications will be apparent to one skilled in the art in light of this disclosure and are intended to fall within the scope of the appended claims.

1. A wavelength converting structure, comprising:
a first layer comprising a first surface, a second surface opposite the first surface, and side surfaces connecting the first and second surfaces, the first layer comprising a first phosphor material and pores in the first phosphor material, the first phosphor material configured to absorb light of a first wavelength and emit light of a second wavelength;
a second layer comprising a first surface, a second surface opposite the first surface, and side surfaces connecting the first and second surfaces, the first surface of the second layer in direct contact with the first surface of the first layer, the second layer comprising the first phosphor material and having a lesser porosity than the first layer.

2. The wavelength converting structure according to claim 1, wherein the second layer does not comprise any pores.

3. The wavelength converting structure according to claim 1, wherein the first phosphor material is YAG.

4. The wavelength converting structure according to claim 1, wherein the light of the second wavelength is visible light.

5. The wavelength converting structure according to claim 1, wherein the light of the second wavelength is infrared light.

6. The wavelength converting structure according to claim 1, wherein a thickness of the first layer may be greater than a thickness of the second layer.

7. The wavelength converting structure according to claim 1, wherein a ratio of the thickness of the first layer with the thickness of the second layer is greater than 3.

8. The wavelength converting structure according to claim 1, wherein the pores each have a diameter between 0.5 μm and 20 μm.

9. The wavelength converting structure according to claim 1, wherein the pores are filled with air.

10. The wavelength converting structure according to claim 1, further comprising a third layer in direct contact with a first surface of the first layer, the third layer comprising the first phosphor material and having a greater porosity than the second layer.

11. The wavelength converting structure according to claim 1, further comprising a third layer in between the first layer and the second layer, the third layer comprising a second phosphor material different from the first phosphor material and having second pores.

12. The wavelength converting structure according to claim 1, further comprising a metal layer disposed on the wavelength converting structure, the metal layer comprising at least one of Ag and Au.

13. The wavelength converting structure according to claim 12, further comprising an intermediate layer in direct contact with the second layer of the wavelength converting structure and the metal layer and comprising SiO₂.

14. The wavelength converting structure according to claim 13, further comprising a Distributed Bragg Reflector having a thickness from 100 nm to 1 microns and disposed between the intermediate layer and the metal layer.

15. A method for making a wavelength converting structure, the method comprising:
forming first tapes by casting and drying a first suspension comprising pore-formers and a first phosphor material;
forming at least one second tape by casting and drying a second suspension that comprises the first phosphor material without comprising the pore-formers;
laminating the first tapes to each other and to the at least one second tape, the first tapes laminated to form a first layer the at least one second tape forming a second layer.
